(19) United States
(12) Patent Application Publication
(10) Pub. No.: US 2024/0215163 A1
(43) Pub. Date: Jun. 27, 2024

(54) SUBSTRATE GLASS CORE PATTERNING FOR CTV IMPROVEMENT AND LAYER COUNT REDUCTION

(71) Applicant: Intel Corporation, Santa Clara, CA (US)

(72) Inventors: Onur OZKAN, Scottsdale, AZ (US); Jacob VEHONSKY, Gilbert, AZ (US); Vinith BEJUGAM, Chandler, AZ (US); Nicholas S. HAEHN, Scottsdale, AZ (US); Andrea NICOLAS FLORES, Chandler, AZ (US); Mao-Feng TSENG, Tempe, AZ (US)

(21) Appl. No.: 18/089,489

(22) Filed: Dec. 27, 2022

(51) Int. Cl. H05K 1/11; H05K 1/03; H05K 1/18

(52) U.S. Cl. CPC H05K 1/112; H05K 1/0306; H05K 1/183; H01L 23/49838

(57) ABSTRACT

Embodiments disclosed herein include a package core. In an embodiment, the package core comprises a substrate with a first surface and a second surface opposite from the first surface. In an embodiment, the substrate comprise glass. In an embodiment, a via is provided through the substrate, where the via is electrically conductive. In an embodiment, a recess is formed into the first surface of the substrate, and a trace is embedded in the recess. In an embodiment, the trace is electrically conductive.

### TECHNICAL FIELD

Embodiments of the present disclosure relate to electronic packages, and more particularly to package substrates with glass cores that include integrated traces.

### BACKGROUND

Electronic packages include a core and buildup layers over and under the core. In some instances, the core is an organic material that can be reinforced with glass fibers or the like. Conductive routing through the core is typically provided using plated through holes. Pads can be provided on the core, but it is typically not possible to provide routing embedded on the core surfaces. As such, routing is limited to being formed in the buildup layers over and under the core.

Providing all routing in the buildup layers is not desirable, since this results in higher density routing in the buildup layers, and/or needing to provide additional buildup layers. Each extra layer results in an increase in the cost of the electronic package. Additionally, plating and lamination (of the buildup layers) uniformity is more difficult between high density routing regions and low density routing regions.

### BRIEF DESCRIPTION OF THE DRAWINGS

FIG. 1A is a cross-sectional illustration of an electronic package with an organic core that includes plated through hole vias, in accordance with an embodiment.

FIG. 1B is a plan view illustration of the core that shows vias through the core but no lateral routing traces on the core, in accordance with an embodiment.

FIG. 2A is a cross-sectional illustration of a core that comprises glass and includes through glass vias and embedded traces, in accordance with an embodiment.

FIG. 2B is a cross-sectional illustration of a core that comprises glass and includes through glass vias with hourglass shaped cross sections and embedded traces, in accordance with an embodiment.

FIG. 2C is a cross-sectional illustration of an embedded trace in the top surface of a core that comprises glass, in accordance with an embodiment.

FIG. 2D is a cross-sectional illustration of an embedded trace in the top surface of a core that comprises glass, where the sidewalls of the embedded trace are sloped, in accordance with an embodiment.

FIG. 3 is a cross-sectional illustration of a glass core with a through glass via and blind features provided into the first and second surface of the glass core, in accordance with an embodiment.

FIG. 4 is a plan view illustration of a glass core that illustrates conductive routing that transitions a first pitch of through glass vias to a second, smaller, pitch of pads that are coupled to overlying circuitry in the buildup layers, in accordance with an embodiment.

FIG. 5A is a cross-sectional illustration of a glass core, in accordance with an embodiment.

FIG. 5B is a cross-sectional illustration of the glass core after latent images for through glass vias and embedded traces are formed with a laser exposure process, in accordance with an embodiment.

FIG. 5C is a cross-sectional illustration of the glass core after via openings and trenches are formed in the glass core, in accordance with an embodiment.

FIG. 5D is a cross-sectional illustration of the glass core after a seed layer is provided over the glass core, in accordance with an embodiment.

FIG. 5E is a cross-sectional illustration of the glass core after a resist layer is provided over the glass core, in accordance with an embodiment.

FIG. 5F is a cross-sectional illustration of the glass core after the through glass vias and the embedded traces are plated, in accordance with an embodiment.

FIG. 5G is a cross-sectional illustration of the glass core after the resist layer is removed, in accordance with an embodiment.

FIG. 5H is a cross-sectional illustration of the glass core after the seed layer is removed, in accordance with an embodiment.

FIG. 5I is a cross-sectional illustration of the glass core after buildup layers are provided above and below the core, in accordance with an embodiment.

FIG. 6 is a cross-sectional illustration of a computing system that includes an electronic package with a glass core that comprises through glass vias and embedded traces, in accordance with an embodiment.

FIG. 7 is a schematic of a computing device built in accordance with an embodiment.

### EMBODIMENTS OF THE PRESENT DISCLOSURE

Described herein are package substrates with glass cores that include integrated traces, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

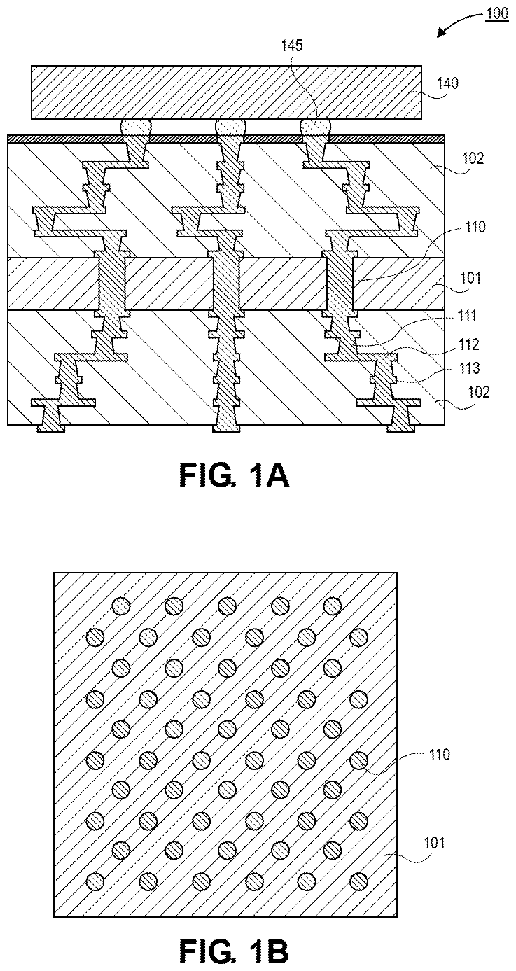

Referring now to FIG. 1A, a cross-sectional illustration of an electronic package 100 is shown, in order to provide context to embodiments disclosed herein. In some instances, the electronic package 100 may comprise a core 101. The core 101 may be an organic core material. The core 101 may be reinforced with glass fibers or the like. In order to provide electrical connections through the core 101, vias 110 are provided. In the illustration of FIG. 1A the vias 110 are solid. Though, in some instances, the vias 110 may be plated through holes (PTHs). That is, the vias 110 may have an air core that is surrounded by a conductive shell. Though, a dielectric or insulating material may also fill the core in some instances. As illustrated, there is no lateral routing on the core 101. Instead, all of the lateral routing is provided in the overlying or underlying buildup layers 102. For example, pads 113, traces 112, and vias 111 may be provided within the buildup layers 102.

The conductive routing in the buildup layers 102 may provide pitch translation functionality. For example, the pads on the bottom of the electronic package 100 may have a first pitch and the pad on the top of the electronic package 100 may have a second smaller pitch. Since the lateral routing is provided only on the buildup layers 102, the routing has a higher density, and additional buildup layers are needed. This increases the cost of the electronic package 100. Additionally uneven routing density within a layer can result in plating uniformity problems. The electronic package 100 may comprise a die 140 with interconnects 145 to connect the die 140 to the pads 113.

Referring now to FIG. 1B, a plan view illustration of the core 101 is shown. As illustrated, the core 101 may include a plurality of vias 110 that are spaced apart from each other. The spacing in FIG. 1B is substantially uniform across the surface of the core 101. However, in some architectures, the via 110 density may not be as uniform as what is shown in FIG. 1B. As such, plating uniformity can be an issue. Additionally, as shown in FIG. 1B, there is no lateral routing provided on the core 101. As such, all lateral routing needs to be implemented in the overlying or underlying buildup layers (not shown in FIG. 1B).

Accordingly, embodiments disclosed herein include electronic packages that enable lateral routing on the core. More particularly, the lateral routing is formed with traces that are embedded into the surfaces of the core. In some embodiments, the core may comprise a glass core. The conductive features may be fabricated in the glass core using a laser assisted etching process. For example, a laser exposure of the glass core generates a latent image of via openings and trenches. The latent image may be characterized by a glass that has a modified microstructure or phase compared to the unexposed regions of the glass core. After laser exposure, the latent images are more susceptible to an etching chemistry (e.g., a wet etching chemistry). Conductive features may then be plated in the via openings and trenches in order to form vias and embedded traces.

Moving lateral routing to the core has several benefits. One benefit is that conductive routing in the buildup layers is reduced. This may result in the need for fewer buildup layers, which reduces cost of the electronic package. In other embodiments, moving conductive routing to the core may lessen the routing density in the buildup layers. This can mitigate plating non-uniformities and improves thickness uniformity.

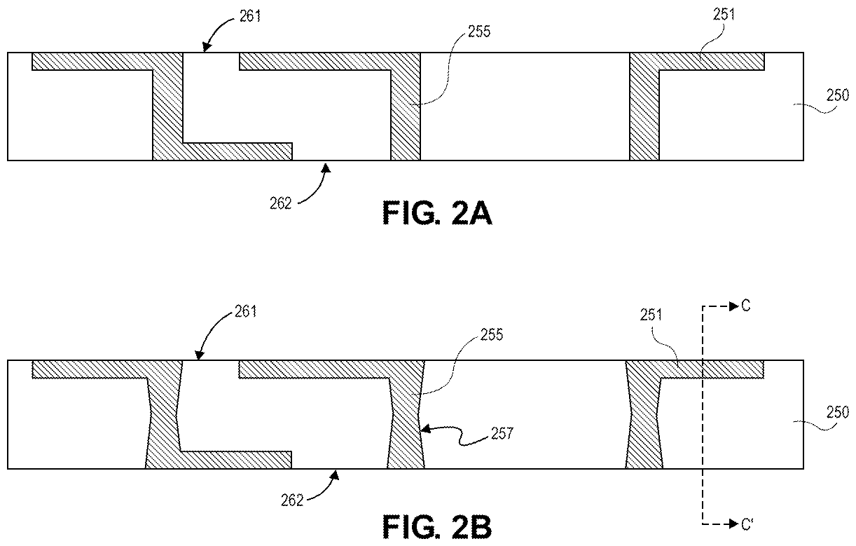

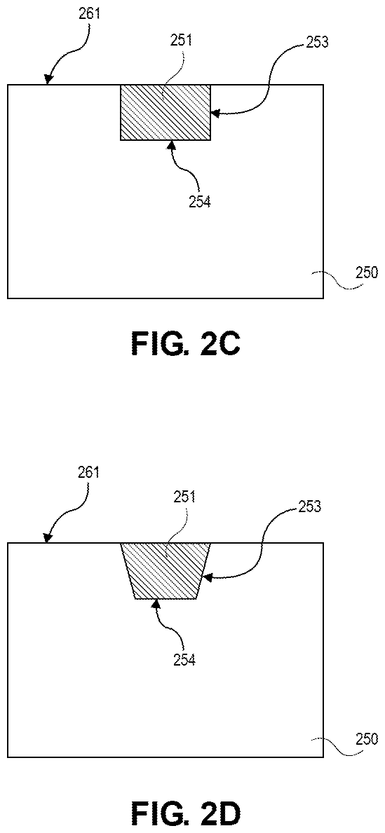

Referring now to FIG. 2A, a cross-sectional illustration of a core 250 is shown, in accordance with an embodiment. In an embodiment, the core 250 may comprise glass. More particularly, the core 250 may comprise substantially all glass. That is, the glass core 250 is different in composition than existing cores (such as core 101) that includes an organic material that is reinforced by glass fibers or the like. In an embodiment, the core 250 may comprise a glass composition that is compatible with laser assisted patterning processes. For example, laser exposure of the core 250 may result in the formation of a latent image. The latent image is then more susceptible to an etching chemistry than the non-exposed regions of the core 250. In an embodiment, the core 250 may comprise a borosilicate glass, a fused silica glass, or the like.

In an embodiment, the core 250 may have any suitable dimensions. In a particular embodiment, a thickness of the core 250 may be between approximately 50 μm and approximately 1,000 μm. As used herein, “approximately” may refer to a range of values that are within ten percent of the stated value. For example, approximately 1,000 μm may refer to a range between 900 μm and 1,100 μm. While a particular range of the thickness of the core 250 is provided herein, it is to be appreciated that thicker or thinner cores 250 may also be used in some embodiments. In an embodiment, the core 250 may have a form factor of an electronic package. In other embodiments, (i.e., at an earlier step in the assembly of electronic packages) the core 250 may be part of a panel or quarter panel. Such, panel level or quarter panel level architectures may ultimately be singulated into cores 250 with an electronic package form factor.

In an embodiment, the core 250 may comprise one or more vias 255. The vias 255 may pass through a thickness of the core 250 between a first surface 261 and an opposite second surface 262. While a set of three vias 255 are shown in FIG. 2A, it is to be appreciated that any number of vias 255 may be included. Additionally, the spacing of the vias 255 may be non-uniform. For example, some areas of the core 250 may have a higher via 255 density than other areas of the core 250. In order to account for plating non-uniformities that may arise from via density differences, dummy features (described in greater detail below) may be used.

In an embodiment, the vias 255 may be substantially solid. That is, there may not be an internal core (i.e., an air core) within the vias 255. Though, in some instances, voids may be formed as a result of limitations in plating high aspect ratio features. Such vias are different than the purposely voided cores used in PTH architectures. Though, ideally, there will be substantially no voids in the vias 255. In an embodiment, the vias 255 may be high aspect ratio features. As used herein, “high aspect ratio” features may refer to a feature that has a depth:width ratio that is approximately 3:1 or greater. In some instances, the vias 255 may have aspect ratios that are 5:1 or greater or 10:1 or greater.

In an embodiment, the core 250 may further comprise lateral traces 251. The lateral traces 251 may be embedded into the top surface 261 and/or the bottom surface 262 of the core 250. The lateral traces 251 may be electrically coupled to vias 255. As such, the lateral position of the vias 255 can be redistributed on the core 250 without the need of overlying buildup layers. In an embodiment, the vias 255 and the lateral traces 251 may comprise copper or the like. The vias 255 and lateral traces 251 may further comprise diffusion barrier layers, adhesion layers, seed layers, and/or the like.

Referring now to FIG. 2B, a cross-sectional illustration of a core 250 is shown, in accordance with an additional embodiment. In an embodiment, the core 250 in FIG. 2B may be substantially similar to the core 250 in FIG. 2A, with the exception of the vias 255. For example, in FIG. 2A, the vias 255 have substantially vertical sidewalls, and in FIG. 2B, the vias 255 have sloped sidewalls 257. The sloped structure of the sidewalls 257 may be the result of the patterning process used to form the vias 255. For example, the laser exposure may result in features that are wider proximate to the top of the core 250 and narrower towards a middle of the core 250.

In the particular embodiment shown in FIG. 2B, the vias 255 have double sloped sidewalls 257. The double sloped sidewalls 257 may be the result of dual sided laser exposure. That is lasers may expose the core 250 from both the top surface 261 and the bottom surface 262. The particular structure shown in FIG. 2B may sometimes be referred to as having an hourglass shaped cross-section. An hourglass shaped cross-section may include a shape that has a top and bottom that are both wider than a middle of the shape. In some instances, the narrowest portion of the via 255 may be at the midpoint of the core 250 between the first surface 261 and the second surface 262. Though, the narrowest portion of the via 255 may be at any location between the first surface 261 and the second surface 262. For example, in the case of a single sided exposure, the width of the via 255 at the first surface 261 may be the widest portion of the via 255, and the width of the via 255 at the second surface 262 may be the narrowest portion of the via 255.

Referring now to FIG. 2C, a cross-sectional illustration of the core 250 in FIG. 2B along line C-C′ is shown, in accordance with an embodiment. As shown, the lateral trace 251 is embedded in the core 250. That is, the lateral trace 251 is set into the first surface 261 of the core 250. For example, the lateral trace 251 may be set within a trench in the core 250. As used herein, “embedded” may refer to a structure that has at least a portion of sidewalls 253 and a bottom surface 254 covered by the substrate in which the structure is embedded. For example, in FIG. 2C, the lateral trace 251 has sidewalls 253 that are entirely covered by the core 250, and the bottom surface 254 is entirely covered by the core 250. The top surface of the lateral trace 251 may not be covered by the core 250 in some embodiments. That is, the lateral trace 251 may not be entirely embedded in the core 250 in some embodiments.

Referring now to FIG. 2D, a cross-sectional illustration of the core 250 is shown, in accordance with an additional embodiment. The cross-section shown in FIG. 2D may be across the width of a lateral trace 251. However, the lateral trace 251 in FIG. 2D may differ from the lateral trace 251 in FIG. 2C because the sidewalls 253 are sloped. For example, sidewalls 253 may be sloped so that a bottom of the lateral trace 251 is narrower than a top of the lateral trace 251. The sloped profile may be the result of a laser assisted patterning used to form the trench in which the lateral trace 251 is plated. Similar to the embodiment shown in FIG. 2C, the lateral trace 251 may be embedded in the core 250. That is, a bottom surface 254 and the sidewall surfaces 253 may be covered by the glass core 250.

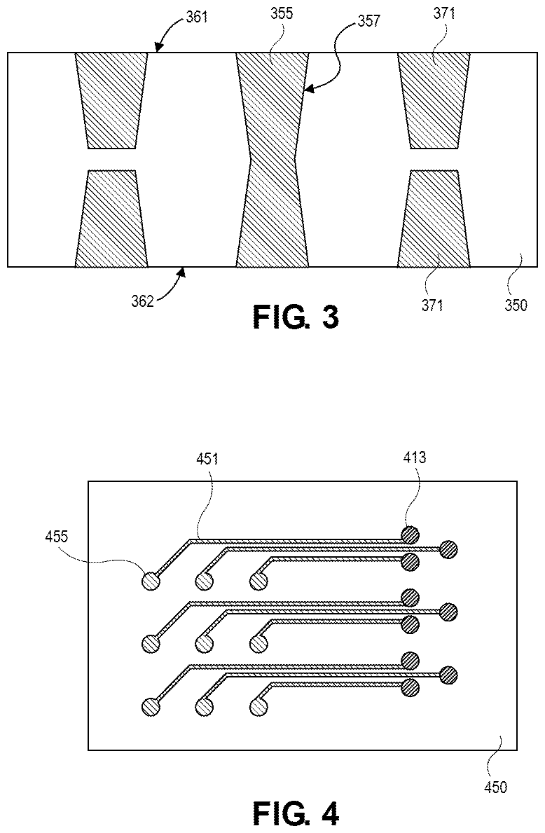

Referring now to FIG. 3, a cross-sectional illustration of a core 350 is shown, in accordance with an embodiment. In an embodiment, the core 350 may be a glass core 350 similar to embodiments described in greater detail above. In an embodiment, the core 350 may comprise one or more vias 355 that pass through a thickness of the core 350 between a first surface 361 and a second surface 362. In an embodiment, the via 355 may have sloped sidewalls 357. For example, the via 355 may have an hourglass shaped cross-section in some embodiments.

In an embodiment, the core 350 may further comprise one or more blind features 371. The blind features 371 may be filled with a conductive material, such as copper. In one embodiment, the blind features 371 may be trenches in order to provide embedded lateral traces across surfaces 361 and 362 of the core 350. In other embodiments, the blind features 371 may be circular or polygonal shaped. Such instances may be useful for providing dummy features in the core. For example, dummy features may be used in order to modify the density of conductive features. More uniform conductive feature density may be beneficial for improving plating uniformity. In some embodiments, the blind features 371 may not be electrically coupled to any additional circuitry of the core 350.

As shown, blind features 371 may extend into, but not through, the thickness of the core 350. In the illustrated embodiment, blind features 371 are aligned over each other. In other embodiments, blind features 371 may be offset from each other. Additionally, blind features 371 may extend more than halfway through the core 350 in some embodiments. While shown as having sloped sidewalls, in some embodiments, the blind features 371 may have substantially vertical sidewalls. The blind features may be formed with a laser assisted patterning process similar to the process used to form the vias 355.

Referring now to FIG. 4, a plan view illustration of a core 450 is shown, in accordance with an embodiment. As shown, an array of vias 455 may be provided through a thickness of the core 450. The vias 455 may have a first pitch. In an embodiment, the vias 455 may be electrically coupled to pads 413 on the surface of the core 450 by lateral traces 451. The pads 413 may have a second pitch that is smaller than the first pitch. That is, the lateral traces 451 may operate to provide pitch translation. As such, pitch translation that would otherwise need to occur in the overlying buildup layers (not shown) can be implemented on the core 450 in previously unused area. As such, routing density in the buildup layers can be reduced and/or the number of buildup layers can be reduced.

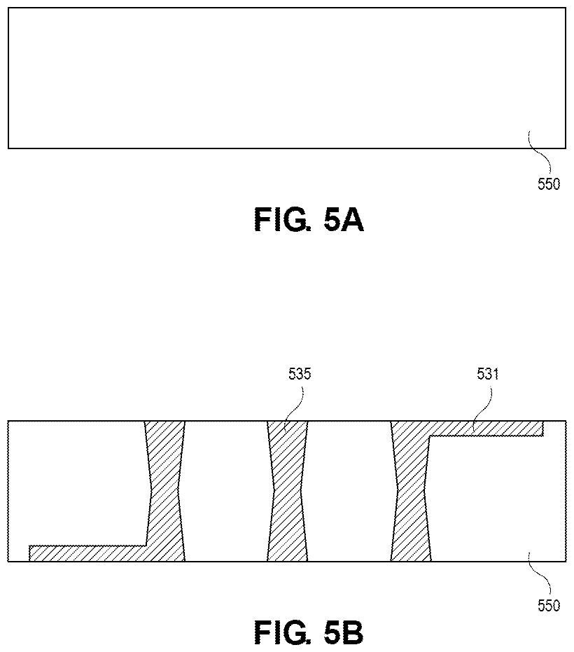

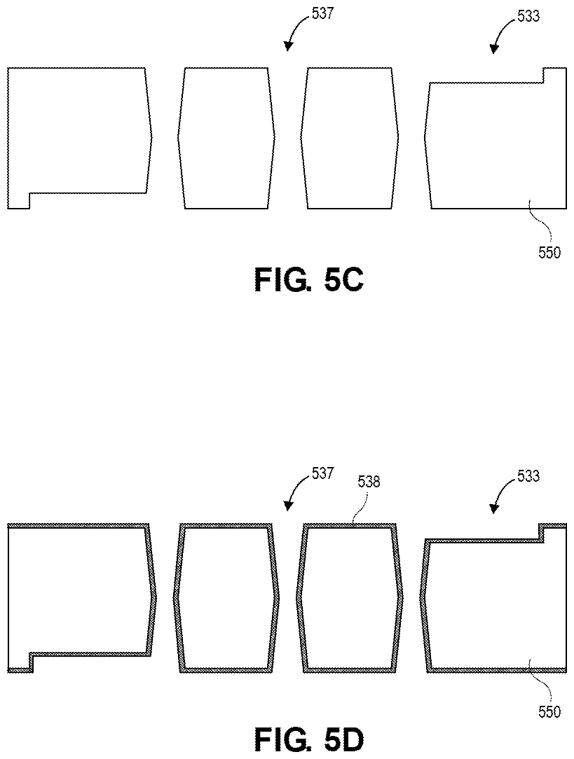

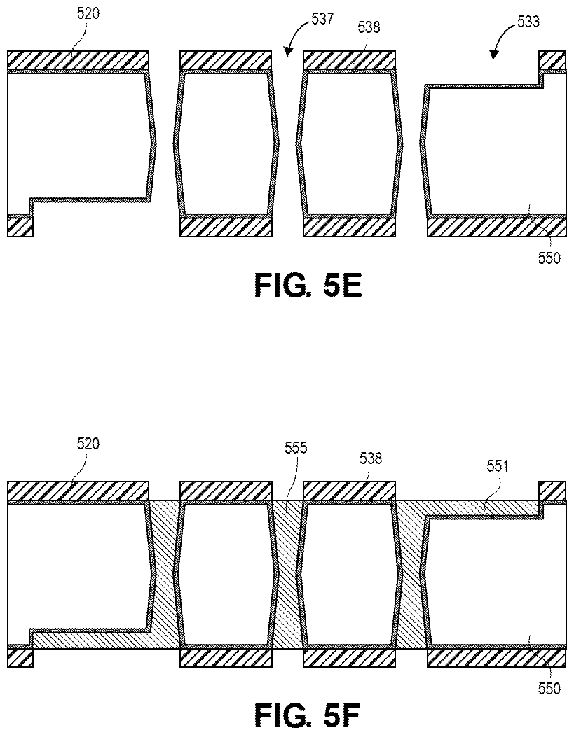

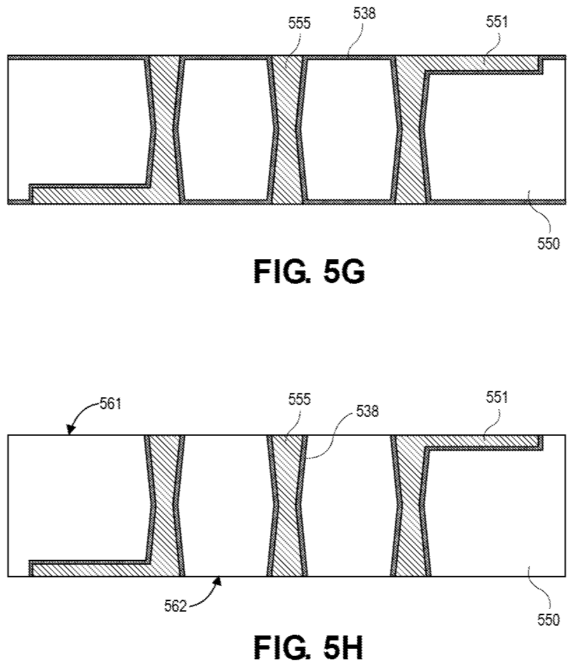

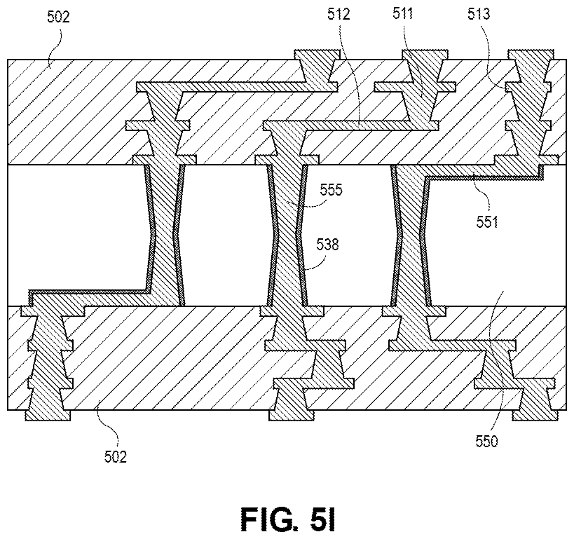

Referring now to FIGS. 5A-5I, a series of cross-sectional illustrations depicting a process for forming a core 550 that comprises glass is shown, in accordance with an embodiment. For example, laser assisted patterning processes can be used to form a latent image in the core 550 that is subsequently etched. Conductive material may then be plated in the openings in the core 550.

Referring now to FIG. 5A, a cross-sectional illustration of a core 550 is shown, in accordance with an embodiment. In an embodiment, the core 550 may comprise glass. That is, the core 550 may substantially comprise only glass. The glass may be a borosilicate glass, a fused silica glass, or the like. In a particular embodiment, the glass may be a glass material that is suitable for laser assisted patterning processes. The core 550 may have any suitable dimensions. In a particular embodiment, a thickness of the core 550 may be between approximately 100 μm and approximately 1,000 μm. Though, thicker or thinner cores 550 may also be used in other embodiments. The form factor of the core 550 may be a panel level or a quarter panel level form factor. Though, in some embodiments, smaller form factors may also be used.

Referring now to FIG. 5B, a cross-sectional illustration of the core 550 after a laser exposure process is shown, in accordance with an embodiment. In an embodiment, the laser exposure process may result in latent images being formed in the core 550. The latent images may be regions where a microstructure and/or phase of the core 550 is changed as a result of laser exposure. For example, the latent image may include via images 535 and/or lateral trace images 531. The via images 535 may extend through a thickness of the core 550. The lateral trace images 531 may be blind features (i.e., features that do not pass entirely through the core 550) that extend out from the via images 535. In an embodiment, the laser exposure may be a dual sided laser exposure. That is, both the top surface and the bottom surface of the core 550 may be exposed by the laser.

Referring now to FIG. 5C, a cross-sectional illustration of the core 550 after the latent images are developed is shown, in accordance with an embodiment. In an embodiment, the latent images may be developed with an etching chemistry, such as a wet etching solution. The etchant may selectively etch the latent images 535 and 531 relative to the unexposed regions of the core 550. In an embodiment, the developing process results in the formation of via openings 537 and trenches 533. The via openings 537 may have sloped sidewalls. For example, the via openings 537 may have hourglass shaped profiles. In an embodiment, the trenches 533 may also have sloped sidewalls. Though, depending on the etching chemistry and the laser exposure process, the sidewalls of the via openings 537 and/or the trenches 533 may be substantially vertical.

Referring now to FIG. 5D, a cross-sectional illustration of the core 550 after a seed layer 538 is deposited is shown, in accordance with an embodiment. The seed layer 538 may be deposited with any suitable deposition process. For example, the seed layer 538 may be deposited with a sputtering process, a physical vapor deposition (PVD) process, a chemical vapor deposition (CVD) process, an atomic layer deposition (ALD) process, or the like. The seed layer 538 may be a conformally deposited layer. This results in the seed layer 538 covering sidewalls of the via openings 537 and sidewalls of the trenches 533. The bottom surface of the trenches 533 may also be covered by the seed layer 538. The seed layer 538 may be any suitable material composition. For example, the seed layer 538 may comprise one or both of copper and titanium, or other conductive material compositions.

Referring now to FIG. 5E, a cross-sectional illustration of the core 550 after a resist layer 520 is applied is shown, in accordance with an embodiment. In an embodiment, the resist layer 520 may be a dry film resist (DFR) or the like. The resist layer 520 may be patterned with a resist patterning operation in order to form openings that align with the via openings 537 and the trenches 533. That is, the seed layer 538 over the top surface and the bottom surface of the core 550 may be covered in order to prevent conductive plating in those areas.

Referring now to FIG. 5F, a cross-sectional illustration of the core 550 after a plating process is shown, in accordance with an embodiment. In an embodiment, the plating process may result in the formation of vias 555 and lateral traces 551. The plating process may be any suitable plating process, such as an electroplating process. In an embodiment, the vias 555 may be high aspect ratio vias (e.g., 3:1 or greater, 5:1 or greater, or 10:1 or greater). The lateral traces 551 may be connected to vias 555 in order to provide pitch translation on the surface of the core 550. In an embodiment, dummy features (not shown) may also be formed using similar patterning and plating processes.

While FIGS. 5E and 5F depict one process for forming the conductive features, it is to be appreciated that embodiments are not limited to such process flows. For example, an electroplating process may be used to deposit the conductive material everywhere (i.e., without the use of a resist layer 520). Subsequent to the plating, a chemical etching or chemical mechanical polishing (CMP) process may be used to remove the plated metal on the top and bottom surfaces.

Referring now to FIG. 5G, a cross-sectional illustration of the core 550 after the resist layer 520 is removed is shown, in accordance with an embodiment. The resist layer 520 may be removed with a resist stripping process, an etching process, or the like. Removal of the resist layer 520 results in the exposure of the underlying seed layer 538 on the top surface and the bottom surface of the core 550.

Referring now to FIG. 5H, a cross-sectional illustration of the core 550 after the seed layer 538 is removed is shown, in accordance with an embodiment. In an embodiment, the seed layer 538 may be removed with a flash etching process, such as a timed etch. The rapid etch allows for the seed layer 538 to be removed without significantly altering the structure of the vias 555 and the lateral traces 551. The seed layer 538 removal operation electrically isolates various structures from each other. However, it is to be appreciated that portions of the seed layer 538 may persist into the final structure along sidewalls of the vias 555 and the sidewalls and bottom of the lateral traces 551.

Referring now to FIG. 5I, a cross-sectional illustration of the core 550 after buildup layers 502 are formed above and below the core 550 is shown, in accordance with an embodiment. In an embodiment, the buildup layers 502 may include conductive routing that is coupled to the vias 555 and the lateral traces 551. The conductive routing may include pads 513, traces 512, and vias 511. The conductive routing in the buildup layers 502 and the conductive routing in the core 550 may provide pitch translation between a bottom of the structure and a top of the structure. For example, pads 513 at the bottom of the structure may have a first pitch, and pads 513 at the top of the structure may have a second, smaller, pitch. At least a portion of the pitch translation may be implemented on the core 550, (i.e., through the use of lateral traces 551).

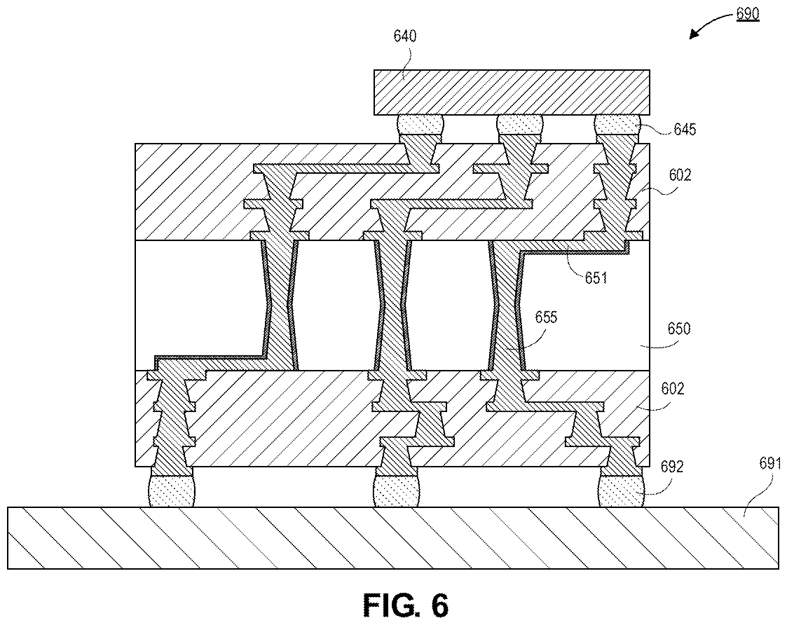

Referring now to FIG. 6, a cross-sectional illustration of a computing system 690 is shown, in accordance with an embodiment. In an embodiment, the computing system 690 may comprise a board 691, such as a printed circuit board (PCB) or the like. In an embodiment, the board 691 may be coupled to a package substrate by interconnects 692. While shown as solder balls, it is to be appreciated that any interconnect architecture (e.g., sockets or the like) may be provided between the board 691 and the package substrate.

In an embodiment, the package substrate comprises a core 650 with buildup layers 602 above and below the core 650. In an embodiment, the core 650 may be a glass core. The core 650 may comprise through glass vias 655 that pass through a thickness of the core 650. Additionally, lateral traces 651 may be provided on the core 650. Particularly, the lateral traces may be at least partially embedded within the core 650.

In an embodiment, one or more dies 640 may be coupled to the package substrate by interconnects 645. The interconnects 645 may be any suitable first level interconnect (FLI) architecture. In an embodiment, the die 640 may comprise a compute die, such as a processor, a graphics processor, a system on a chip (SoC), an XPU, a communications chip, an ASIC, or the like. The one or more dies 640 may further comprise a memory die in some embodiments.

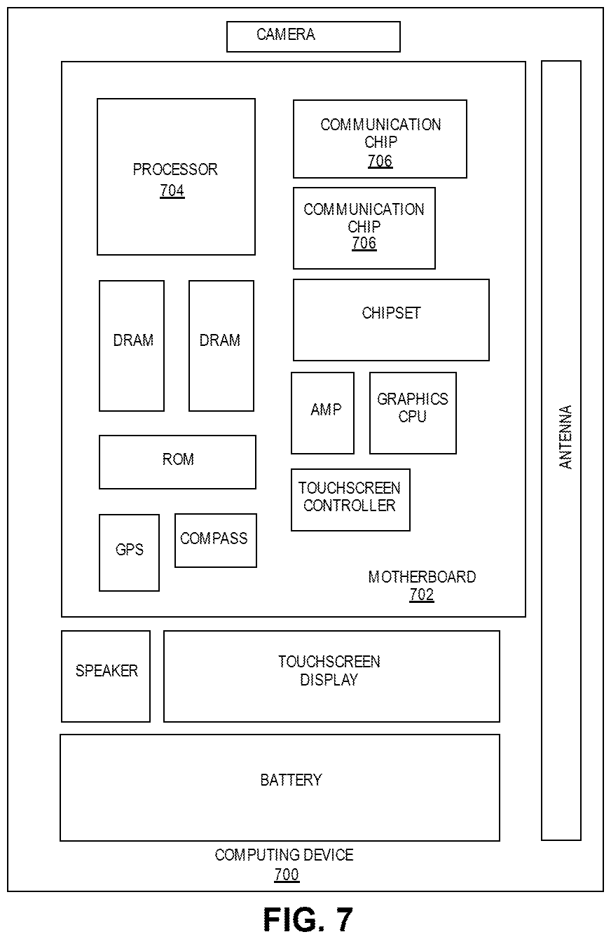

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be part of an electronic package that comprises a glass core with through glass vias and embedded lateral traces, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be part of an electronic package that comprises a glass core with through glass vias and embedded lateral traces, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 1000 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package core, comprising: a substrate with a first surface and a second surface opposite from the first surface, wherein the substrate comprise glass; a via through the substrate, wherein the via is electrically conductive; a recess into the first surface of the substrate; and a trace embedded in the recess, wherein the trace is electrically conductive.

Example 2: the package core of Example 1, wherein the trace is electrically coupled to the via.

Example 3: the package core of Example 1 or Example 2, wherein the trace and the via comprise copper.

Example 4: the package core of Examples 1-3, wherein the recess has tapered sidewalls.

Example 5: the package core of Examples 1-4, wherein the via has tapered sidewalls.

Example 6: the package core of Example 5, wherein the via has an hourglass shaped cross-section.

Example 7: the package core of Examples 1-6, further comprising: a recess in the second surface of the substrate; and a second trace in the recess in the second surface of the substrate.

Example 8: the package core of Examples 1-7, further comprising: a blind hole into the first surface of the substrate, wherein the blind hole is filled with an electrically conductive material.

Example 9: the package core of Examples 1-8, wherein the substrate comprises substantially all glass.

Example 10: the package core of Examples 1-9, further comprising: organic buildup layers over and under the substrate.

Example 11: the package core of Examples 1-10, wherein the substrate is coupled to a processor of a computing system, and wherein the computing system is part of a personal computer, a server, a mobile device, a tablet, or an automobile.

Example 12: a package substrate, comprising: a core; buildup layers above and below the core; conductive routing through the core and the buildup layers, wherein a first end of the conductive routing has first pads with a first pitch and a second end of the conductive routing has second pads with a second pitch that is smaller than the first pitch, and wherein the conductive routing comprises at least one trace on the core and a via through the core.

Example 13: the package substrate of Example 12, wherein the at least one trace is embedded in the core.

Example 14: the package substrate of Example 12 or Example 13, wherein the at least one trace has sloped sidewalls.

Example 15: the package substrate of Examples 12-14, wherein the via has tapered sidewalls.

Example 16: the package substrate of Example 15, wherein the via has an hourglass shaped cross-section.

Example 17: the package substrate of Examples 12-16, wherein the first pads are coupled to a board, and wherein the second pads are coupled to a die.

Example 18: a computing system, comprising: a board; a package substrate coupled to the board, wherein the package substrate comprises: a core, wherein the core comprises glass; a via through the core; a trace embedded in the core; and buildup layers over and under the core; and a die coupled to the package substrate.

Example 19: the computing system of Example 18, wherein the die is a processor, a system on a chip (SoC), an XPU, a graphics processor, a communication chip, or an ASIC.

Example 20: the computing system of Example 18 or Example 19, wherein the computing system is part of a personal computer, a server, a mobile device, a tablet, or an automobile.

What is claimed is:

1. A package core, comprising:
a substrate with a first surface and a second surface opposite from the first surface, wherein the substrate comprise glass;
a via through the substrate, wherein the via is electrically conductive;
a recess into the first surface of the substrate; and
a trace embedded in the recess, wherein the trace is electrically conductive.

2. The package core of claim 1, wherein the trace is electrically coupled to the via.

3. The package core of claim 1, wherein the trace and the via comprise copper.

4. The package core of claim 1, wherein the recess has tapered sidewalls.

5. The package core of claim 1, wherein the via has tapered sidewalls.

6. The package core of claim 5, wherein the via has an hourglass shaped cross-section.

7. The package core of claim 1, further comprising:
a recess in the second surface of the substrate; and
a second trace in the recess in the second surface of the substrate.

8. The package core of claim 1, further comprising:
a blind hole into the first surface of the substrate, wherein the blind hole is filled with an electrically conductive material.

9. The package core of claim 1, wherein the substrate comprises substantially all glass.

10. The package core of claim 1, further comprising:
organic buildup layers over and under the substrate.

11. The package core of claim 1, wherein the substrate is coupled to a processor of a computing system, and wherein the computing system is part of a personal computer, a server, a mobile device, a tablet, or an automobile.

12. A package substrate, comprising:
a core;
buildup layers above and below the core;
conductive routing through the core and the buildup layers, wherein a first end of the conductive routing has first pads with a first pitch and a second end of the conductive routing has second pads with a second pitch that is smaller than the first pitch, and wherein the conductive routing comprises at least one trace on the core and a via through the core.

13. The package substrate of claim 12, wherein the at least one trace is embedded in the core.

14. The package substrate of claim 12, wherein the at least one trace has sloped sidewalls.

15. The package substrate of claim 12, wherein the via has tapered sidewalls.

16. The package substrate of claim 15, wherein the via has an hourglass shaped cross-section.

17. The package substrate of claim 12, wherein the first pads are coupled to a board, and wherein the second pads are coupled to a die.

18. A computing system, comprising:
a board;
a package substrate coupled to the board, wherein the package substrate comprises:
a core, wherein the core comprises glass;
a via through the core;
a trace embedded in the core; and
buildup layers over and under the core; and
a die coupled to the package substrate.

19. The computing system of claim 18, wherein the die is a processor, a system on a chip (SoC), an XPU, a graphics processor, a communication chip, or an ASIC.

20. The computing system of claim 18, wherein the computing system is part of a personal computer, a server, a mobile device, a tablet, or an automobile.
